(19) United States
(12) Patent Application Publication
(10) Pub. No.: US 2025/0194383 A1
(43) Pub. Date: Jun. 12, 2025

(54) DISPLAY DEVICE

(71) Applicant: Samsung Display Co., Ltd., Yongin-Si (KR)

(72) Inventors: Suk Hoon KANG, Yongin-si (KR); Israel Esteban LAZO MARTINEZ, Yongin-si (KR); Sung Hwan HONG, Yongin-si (KR)

(21) Appl. No.: 18/822,466

(22) Filed: Sep. 3, 2024

(30) Foreign Application Priority Data
Dec. 7, 2023 (KR) 10-2023-0176532

(51) Int. Cl. H10K 59/80; H10K 59/122; H10K 59/38

(52) U.S. Cl. CPC H10K 59/879; H10K 59/122; H10K 59/38

(57) ABSTRACT

A display device includes a substrate, a light emitting element disposed in an emission area on the substrate, and a light conversion layer disposed on the light emitting element to overlap the light emitting element, the light conversion layer including banks, a light conversion pattern disposed between adjacent banks, and a plurality of refractive layer disposed on the banks. The plurality of refractive layers include a first refractive layer disposed on the banks and having a first refractive index and a second refractive layer disposed on the banks on the first refractive layer and having a second refractive index different from the first refractive index.

### CROSS-REFERENCE TO RELATED APPLICATION

The present application claims priority under 35 U.S.C. § 119 (a) to Korean patent application number 10-2023-0176532, filed on Dec. 7, 2023, the entire disclosure of which is incorporated by reference in its entirety herein.

### BACKGROUND

### 1. Technical Field

The present disclosure generally relates to a display device.

### 2. Related Art

Recently, as interest in information displays is increased, research and development of display devices have been continuously conducted.

The above information disclosed in this Related Art section is only for enhancement of understanding of the background of the disclosure and therefore it may contain information that does not form the prior art that is already known in this country to a person of ordinary skill in the art.

### SUMMARY

Embodiments provide a display device having improved display quality.

In accordance with an aspect of the present disclosure, there is provided a display device including: a substrate; a light emitting element disposed in an emission area on the substrate; and a light conversion layer disposed on the light emitting element to overlap the light emitting element, the light conversion layer including banks, a light conversion pattern disposed between adjacent banks, and a plurality of refractive layer disposed on the banks, wherein the plurality of refractive layers include a first refractive layer disposed on the banks and having a first refractive index and a second refractive layer disposed on the banks on the first refractive layer and having a second refractive index different from the first refractive index.

The first refractive index may be lower than the second refractive index.

The first refractive layer and the second refractive layer may be alternatingly and repeatedly disposed on the bank.

The plurality of refractive layers may further include: a third refractive layer disposed on the second refractive layer, the third refractive layer having a refractive index lower than the second refractive index; and a fourth refractive layer disposed on the third refractive layer, the fourth refractive layer having a refractive index higher than the third refractive index.

The plurality of refractive layers may further include a third refractive layer disposed on the second refractive layer, the third refractive layer having a refractive index different from the second refractive index. Each of the first refractive index and the third refractive index may be higher than the second refractive index.

The plurality of refractive layers may further include: a fourth refractive layer disposed on the third refractive layer, the fourth refractive layer having a refractive index lower than the third refractive index; and a fifth refractive layer disposed on the fourth refractive layer, the fifth refractive layer having a refractive index higher than the fourth refractive index.

Each of the plurality of refractive layers may include at least one of an organic material, an inorganic material, and a reflective metal.

Each of the plurality of refractive layers may have a predetermined thickness such that at least some of lights incident from the light emitting element form constructive interference.

The plurality of refractive layers may have a thickness of 1 nm or more and 10000 nm or less.

The banks may include at least one of an organic material, an inorganic material, and a metal. The banks may further include a light scatterer.

One of the banks may include a first side surface facing the light conversion pattern, a second side surface opposite to the first side surface, and a top surface which connects the first side surface and the second side surface to each other and is opposite to the substrate. The first refractive layer may be in contact with the first side surface and the second side surface.

The first refractive layer may be in contact with the top surface.

The banks may further include a liquid repellent additive.

The one of the banks may include a first portion disposed adjacent to the top surface and a second portion disposed between the first portion and the substrate. The first portion may have hydrophobicity and the second portion may have hydrophilicity.

The display device may further include a capping layer covering the light conversion layer. The capping layer and the first portion may be in direct contact with each other.

The light conversion layer may further include a liquid repellent layer.

The liquid repellent layer may include a first portion disposed adjacent to the top surface and a second portion disposed between the first portion and the substrate. The first portion may have hydrophobicity and the second portion may have hydrophilicity.

The display device may further include a capping layer covering the light conversion layer. The first portion may be disposed between the banks and the capping layer. The banks and the first portion may be in direct contact with each other.

The one of the banks may have a square shape, a rectangular shape, or a trapezoidal shape in a cross-sectional view.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a display device in accordance with embodiments of the present disclosure.

FIG. 2 is a plan view of a display panel shown in FIG. 1.

FIG. 3 is a sectional view of the display panel shown in FIG. 1.

FIG. 4 is a circuit diagram illustrating an embodiment of a pixel included in the display device shown in FIG. 1.

FIG. 5 is a sectional view taken along line I-I′ shown in FIG. 2.

FIGS. 6, 7, 8, 9, 10, 11, 12 and 13 are enlarged views illustrating portion A shown in FIG. 5 in accordance with various embodiments of the display panel.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

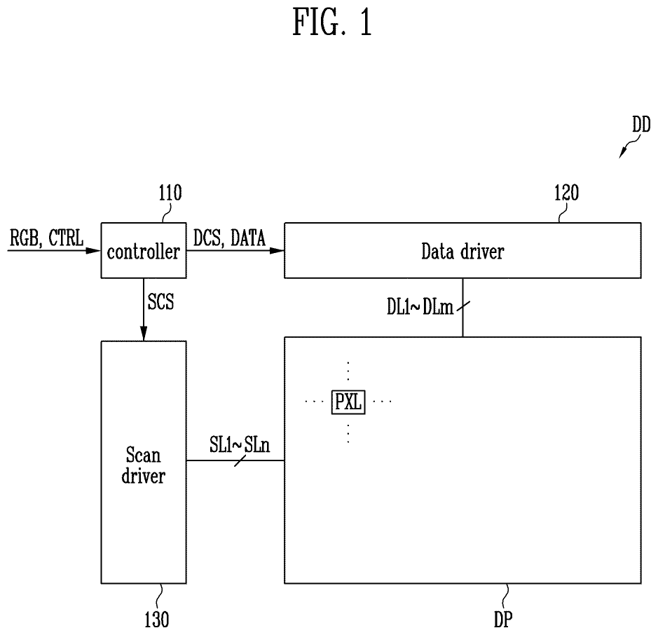

FIG. 1 is a block diagram illustrating a display device in accordance with embodiments of the present disclosure.

Referring to FIG. 1, the display device DD may include a display panel DP, a controller 110, a data driver 120, and a scan driver 130.

The display panel DP may include a plurality of pixels PXL. The display panel DP may include data lines DL1 to DLm and scan lines SL1 to SLn. The data lines DL1 to DLm and the scan lines SL1 to SLn may be disposed on the display panel DP while intersecting each other. The plurality of pixels PXL in the display panel DP may be electrically connected to the data lines DL1 to DLm and the scan lines SL1 to SLn.

The display panel DP may include various types of panels such as an Organic Light Emitting Diode (OLED) panel. The kind of lines disposed in the display panel DP may vary according to a pixel structure, a panel type, and the like.

The controller 110 may control operations of the data driver 120 and the scan driver 130. The controller 110 may provide a first control signal SCS to the scan driver 130 to apply a scan signal to the scan lines SL1 to SLn. The controller 110 may provide the data driver 120 with an image data signal DATA obtained by converting a data format of an image signal to be suitable for interface specifications of the data driver 120. When the scan signal is applied to the scan lines SL1 to SLn, the controller 110 may provide a second control signal DCS to the data driver 120 to apply data voltages to the data lines DL1 to DLm.

The controller 110 may be a timing controller used in ordinary display techniques. The controller 110 may be a control device capable of performing other control functions in addition to a timing control function which is performed by the timing controller.

The data driver 120 may output data signals to the data lines DL1 to DLm. For example, the data driver 120 may receive the second control signal DCS and the image data signal DATA from the controller 110. The data driver 120 may convert the image data signal DATA into data signals, and output the data signals to the data lines DL1 to DLm. The data signals may be analog voltages corresponding to grayscale values of the image data signal DATA. That is, when a specific scan line is selected by the scan driver 130, the data driver 120 may supply data voltages in an analog form to the data lines DL1 to DLm.

The scan driver 130 may receive the first control signal SCS from the controller 110. The scan driver 130 may output a scan signal to the scan lines SL1 to SLn. The scan driver 130 may sequentially supply scan signals to the scan lines SL1 to SLn according to the first control signal SCS from the controller 110. Pixels PXL receiving each scan signal may receive analog voltages of grayscale values corresponding to the image data signal DATA, and output light with a luminance corresponding to the received analog voltages in response to an emission control signal. Accordingly, an image may be displayed on the display panel DP.

Meanwhile, for convenience of description, it is illustrated in FIG. 1 that the data driver 120 and the scan driver 130 are components separate from each other. However, the present disclosure is not limited thereto. That is, at least a portion of the data driver 120 and the scan driver 130 may be integrated into one driving circuit, one module, or the like.

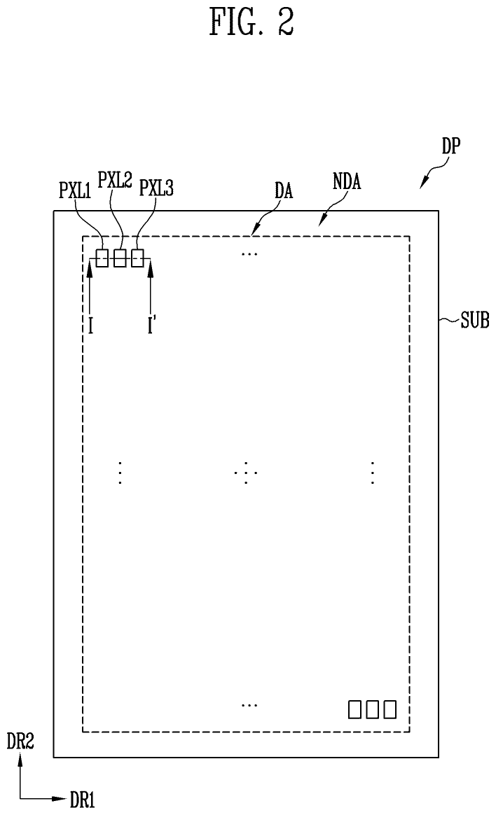

FIG. 2 is a plan view of the display panel shown in FIG. 1.

Referring to FIG. 2, the display panel DP and a substrate SUB for forming the same may include a display area DA for displaying an image and a non-display area NDA except the display area DA. The display area DA may constitute a screen on which the image is displayed, and the non-display area NDA may be an area except the display area DA.

For convenience of description, in FIG. 2, a structure of the display panel DP will be briefly illustrated based on the display area DA. However, although not shown in FIG. 2, at least one driving circuit (e.g., at least one of a scan driver and a data driver), lines, and/or pads may be further disposed in the display panel DP.

A plurality of pixel units may be disposed in the display area DA. Each pixel unit may include a first pixel PXL1, a second pixel PXL2, and/or a third pixel PXL3. For clear and brief description, a first pixel PXL1, a second pixel PXL2, and a third pixel PXL3, which are included in one pixel unit, are illustrated in FIG. 2. Similarly, it may be understood that another pixel unit includes a first pixel PXL1, a second pixel PXL2, and a third pixel PXL3.

Hereinafter, when at least one pixel among the first pixel PXL1, the second pixel PXL2, and the third pixel PXL3 is arbitrarily designated or when two or more kinds of pixels among the first pixel PXL1, the second pixel PXL2, and the third pixel PXL3 are inclusively designated, the corresponding pixel or the corresponding pixels will be referred to as “a pixel PXL” or “pixels PXL.”

The pixels PXL may be regularly arranged according to a stripe structure, a PENTILE™ structure, or the like. However, the arrangement structure of the pixels PXL is not limited thereto, and the pixels PXL may be arranged in the display area DA by using various structures and/or methods.

In some embodiments, two or more pixels PXL emitting lights of different colors may be arranged in the display area DA. In an example, a first pixel PXL1 emitting light of a first color, a second pixel PXL2 emitting light of a second color, and a third pixel PXL3 emitting light of a third color may be arranged in the display area DA. At least one first pixel PXL1, a least one second pixel PXL2, and at least one third pixel PXL3, which are disposed adjacent to each other, may constitute one pixel unit capable of emitting lights of various colors. For example, the first pixel PXL1 may be a red pixel emitting red light, the second pixel PXL2 may be a green pixel emitting green light, and the third pixel PXL3 may be a blue pixel emitting blue light. However, the present disclosure is not limited thereto.

However, in FIG. 2, it is illustrated that one first pixel PXL1, one second pixel PXL2, and one third pixel PXL3, which constitute the pixel unit, are illustrated. However, the present disclosure is not necessarily limited thereto. For example, the pixel unit may include one first pixel PXL1, two second pixels PXL2, and one third pixel PXL3.

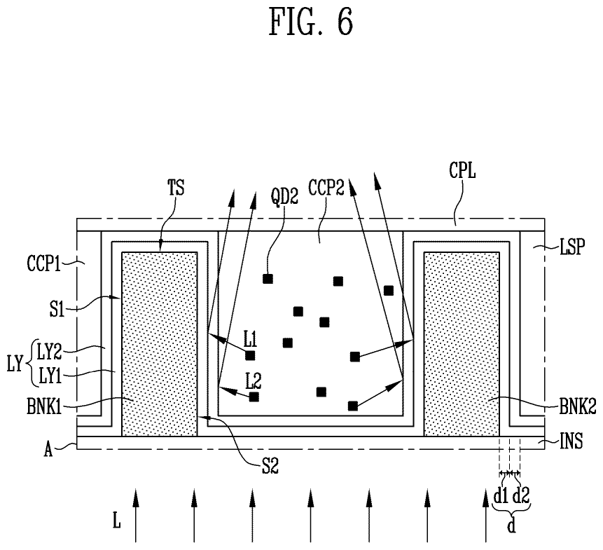

The first pixel PXL1, the second pixel PXL2, and the third pixel PXL3 may have, as light sources, a first light emitting element LD1 (see FIG. 6), a second light emitting element LD2 (see FIG. 6), and a third light emitting element LD3 (see FIG. 6), respectively. However, the color of light emitted from each pixel PXL may be variously altered.

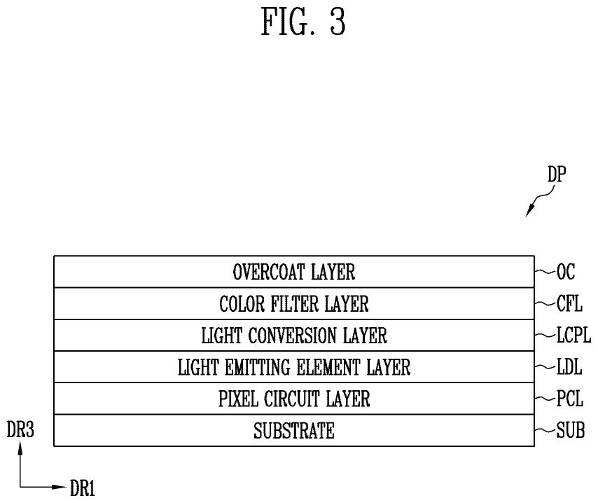

FIG. 3 is a sectional view of the display panel shown in FIG. 1.

Referring to FIG. 3, the display panel DP may include a substrate SUB, a pixel circuit layer PCL, a light emitting element layer LDL, a light conversion layer LCPL, a color filter layer CFL, and an overcoat layer OC.

The substrate SUB may include a semiconductor substrate. The substrate SUB may include a silicon bulk wafer or an epitaxial wafer. The epitaxial wafer may include an epitaxial layer which has crystalline structure grown on a bulk substrate through an epitaxial process. The substrate SUB is not limited to the bulk wafer or the epitaxial wafer, and may be formed using various wafers including a polished wafer, an annealed wafer, a Silicon On Insulator (SOI) wafer, and the like, or various insulating substrates which includes a rigid or flexible substrate.

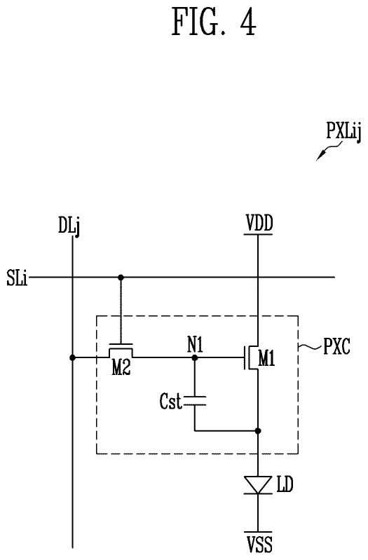

The pixel circuit layer PCL may be disposed on the substrate SUB, and include circuit elements of a pixel circuit (see FIG. 4) and at least one insulating layer located between the circuit elements. The circuit elements may include a plurality of transistors and signal lines connected to the transistors. In an example, each of the transistors may be a Metal Oxide Semiconductor Field Effect Transistor (MOSFET), but the present disclosure is not limited thereto. The circuit element may include a gate electrode, source/drain regions, and a channel region.

The substrate SUB and the pixel circuit layer PCL, which are described above, may be formed by a semiconductor process using semiconductor manufacturing equipment, but the present disclosure is not limited thereto.

The light emitting element layer LDL may include a light emitting element LD (see FIG. 4) emitting light. The light emitting element LD may be located in each of first to third pixels PXL1 to PXL3. The light emitting element LD may include a first electrode, a light emitting layer, and a second electrode. The first electrode may be an anode electrode of the light emitting element LD, and the second electrode may be a cathode electrode of the light emitting element LD.

The light conversion layer LCPL may be disposed on the light emitting element layer LDL. The light conversion layer LCPL may change a wavelength (or color) of light emitted from the light emitting element layer LDL using a quantum dot. The light conversion layer LCPL may be formed on the light emitting element layer LDL through a continuous process.

However, the light conversion layer LCPL is provided separately from the light emitting element layer LDL. However, the present disclosure is not limited thereto. For example, the light emitting element provided in the light emitting element layer LDL may be implemented as a light emitting element (quantum dot display element) emitting light by changing a wavelength of emitted light using a quantum dot.

The color filter layer CFL may be disposed on the light conversion layer LCPL. The color filter layer CFL may selectively transmit light emitted from each light emitting element LD in an image display direction (or front direction) of the display device DD. However, the present disclosure is not limited thereto.

The overcoat layer OC may be disposed on the color filter layer CFL. The overcoat layer OC may be a protective layer covering lower members including the color filter layer CFL and protecting the lower members from external influence. Also, the overcoat layer OC may be a planarization layer, and include an organic material. However, the present disclosure is not limited thereto.

A film layer (not shown) may be further disposed on the overcoat layer OC. The film layer (not shown) may include at least one of a polyethylene terephthalate (PET) film, a low reflective film, a polarizing film, and a transmittance controllable film. The overcoat layer OC which is not included in each pixel PXL and is a separate component is described as an example, the present disclosure is not limited thereto. The overcoat layer OC may be a partial component included in each pixel PXL.

FIG. 4 is a circuit diagram illustrating an embodiment of the pixel included in the display device shown in FIG. 1.

For convenience of description, a pixel PXLij disposed on an ith row and a jth column is exemplarily illustrated in FIG. 4.

Referring to FIG. 4, the pixel PXLij may include a pixel circuit PXC connected to an ith scan line SLi and a jth data line DLj and a light emitting element LD connected to the pixel circuit PXC.

In some embodiments, the light emitting element LD may be an organic light emitting diode. Also, the light emitting element LD may be an inorganic light emitting diode such as a micro LED (light emitting diode) or a quantum dot light emitting diode. Also, the light emitting element LD may be an element which includes a combination of an organic material and an inorganic material.

The pixel circuit PXC may include first and second transistors M1 and M2 and a storage capacitor Cst.

In some embodiments, the first transistor M1 may include a drain electrode connected to a first power source VDD, a source electrode connected to a pixel electrode (e.g., an anode electrode of the light emitting element LD), and a gate electrode connected to a first node N1. In some embodiments, the drain electrode and the source electrode of the first transistor M1 may be reversed to each other according to a polarity of a voltage applied to the first transistor M1 and/or a type of the first transistor M1.

The first transistor M1 may control a driving current flowing from the first power source VDD to a second power source VSS via the light emitting element LD, corresponding to a voltage of the first node N1. That is, the first transistor M1 may be a driving transistor which controls the driving current of the pixel PXLij. In some embodiments, the first power source VDD and the second power source VSS may be a high-potential pixel power source and a low-potential pixel power source, respectively.

In some embodiments, the second transistor M2 may include a drain electrode connected to the jth data line DLj, a source electrode connected to the first node N1, and a gate electrode connected to the ith scan line SLi. In some embodiments, the drain electrode and the source electrode of the second transistor M2 may be reversed to each other according to a polarity of a voltage applied to the second transistor M2 and/or a type of the second transistor M2. The second transistor M2 may be turned on when a scan signal having a gate-on voltage (e.g., a high voltage) is supplied from the ith scan line SLi. When the second transistor M2 is turned on, the jth data line DLj and the first node N1 may be electrically connected to each other. That is, the second transistor M2 may be a switching transistor which controls connection between the pixel PXLij and the jth data line DLj.

In some embodiments, the storage capacitor Cst may be connected between one electrode, e.g., the source electrode of the first transistor M1 and the first node N1. The storage capacitor Cst may store a voltage corresponding to a data signal supplied to the first node N1, and maintain the stored voltage during a predetermined period. Meanwhile, in some embodiments, the connection position of the storage capacitor Cst may be changed. For example, the storage capacitor Cst may be connected between the first power source VDD and the first node N1.

In some embodiments, the light emitting element LD may be connected between the first transistor M1 and the second power source VSS. In an example, the light emitting element LD may include the anode electrode connected to the source electrode of the first transistor M1 and a cathode electrode connected to the second power source VSS. The light emitting element LD may emit light with a luminance corresponding to the driving current controlled by the first transistor M1.

Although an embodiment in which the first and second transistors M1 and M2 are implemented with an N-type transistor is disclosed in FIG. 4, the present disclosure is not limited thereto. For example, at least one of the first and second transistors M1 and M2 may be implemented with a P-type transistor.

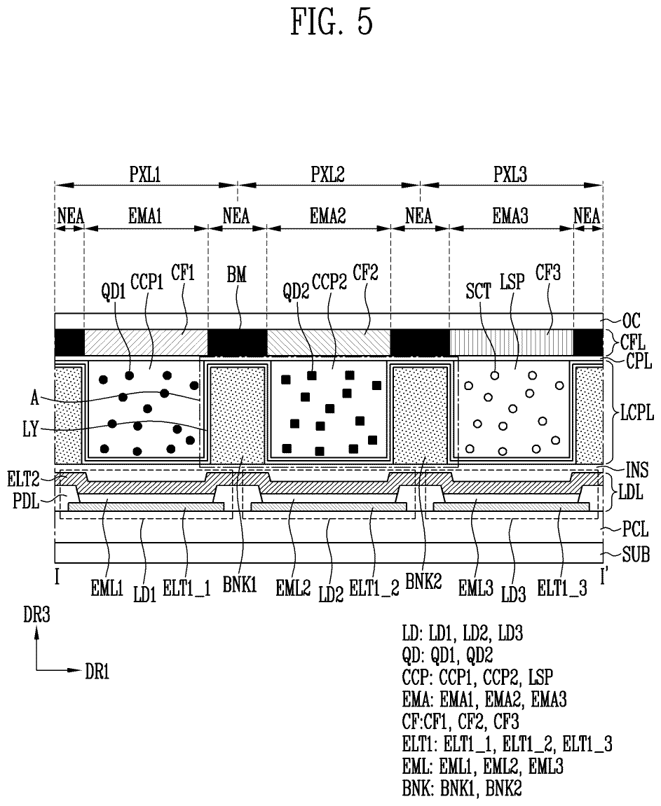

FIG. 5 is a sectional view taken along line I-I′ shown in FIG. 2.

Referring to FIG. 5, the display panel DP may include a substrate SUB, a pixel circuit layer PCL, a light emitting element layer LDL, an insulating layer INS, a light conversion layer LCPL, a capping layer CPL, a color filter layer CFL, and an overcoat layer OC.

The light emitting element layer LDL may include a first light emitting element LD1 located in a first pixel PXL1, a second light emitting element LD2 located in a second pixel PXL2, and a third light emitting element LD located in a third pixel PXL3. Also, the light emitting element layer LDL may include a pixel defining layer PDL.

The first to third light emitting elements LD1 to DL3 may include first electrodes ELT1, light emitting layers EML, and a second electrode ELT2.

The first light emitting element LD1 may include a (1_1)th electrode ELT1_1, a first light emitting layer EML1, and the second electrode ELT2. The second light emitting element LD2 may include a (1_2)th electrode ELT1_2, a second light emitting layer EML2, and the second electrode ELT2. The third light emitting element LD3 may include a (1_3)th electrode ELT1_3, a third light emitting layer EML3, and the second electrode ELT2.

Each of the (1_1)th electrode ELT1_1, the (1_2)th electrode ELT1_2, and the (1_3)th electrode ELT1_3 may be provided and/or formed on the pixel circuit layer PCL of a corresponding pixel. In an example, the (1_1)th electrode ELT1_1, the (1_2)th electrode ELT1_2, and the (1_3)th electrode ELT1_3 may be formed through the same process to include the same material and be located in the same layer. For example, the (1_1)th electrode ELT1_1, the (1_2)th electrode ELT1_2, and the (1_3)th electrode ELT1_3 may be provided and/or formed on an insulating layer of the pixel circuit layer PCL having a flat surface.

The (1_1)th electrode ELT1_1, the (1_2)th electrode ELT1_2, and the (1_3)th electrode ELT1_3 may be disposed to be spaced apart from each other. The (1_1)th electrode ELT1_1 may be an anode electrode of the first light emitting element LD1, the (1_2)th electrode ELT1_2 may be an anode electrode of the second light emitting element LD2, and the (1_3)th electrode ELT1_3 may be an anode electrode of the third light emitting element LD3.

The (1_1)th electrode ELT1_1, the (1_2)th electrode ELT1_2, and the (1_3)th electrode ELT1_3 may include a reflective material such that light emitted from the light emitting layers EML advances in the image display direction. In an example, the (1_1)th electrode ELT1_1, the (1_2)th electrode ELT1_2, and the (1_3)th electrode ELT1_3 may include a conductive material (or substance). For example, the (1_1)th electrode ELT1_1, the (1_2)th electrode ELT1_2, and the (1_3)th electrode ELT1_3 may include metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, this is merely illustrative, and each of the (1_1)th electrode ELT1_1, the (1_2)th electrode ELT1_2, and the (1_3)th electrode ELT1_3 may be provided and/or formed as a multi-layer in which at least two materials among metals, alloys, conductive oxides, and conductive polymers are stacked.

The pixel defining layer PDL may be a structure which is located in a non-emission area NEA and defines first to third emission areas EMA1 to EMA3. In an example, the pixel defining layer PDL may be a structure which is located on the pixel circuit layer PCL in the non-emission area NEA, defines the first emission area EMA1 of the first pixel PXL1, defines the second emission area EMA2 of the second pixel PXL2, and defines the third emission area EMA3 of the third pixel PXL3.

The pixel defining layer PDL may be an organic insulating layer including an organic material. The organic material may include acrylic resin, epoxy resin, phenolic resin, polyamide resin, polyimide resin, and the like. In some embodiments, the pixel defining layer PDL may include a light absorption material or have a light absorber coated thereon, to absorb light introduced from the outside. For example, the pixel defining layer PDL may include a carbon-based black pigment. However, the present disclosure is not limited thereto.

The pixel defining layer PDL may protrude in a third direction DR3 from a surface (or top surface) of the pixel circuit layer PCL.

The first light emitting layer EML1 may be disposed on the (1_1)th electrode ELT1_1 exposed by the pixel defining layer PDL. The second light emitting layer EML2 may be disposed on the (1_2)th electrode ELT1_2 exposed by the pixel defining layer PDL. The third light emitting layer EML3 may be disposed on the (1_3)th electrode ELT1_3 exposed by the pixel defining layer PDL.

The first to third light emitting layers EML1 to EML3 may constitute the light emitting layers EML of the first to third pixels PXL1 to PXL3. The light emitting layers EML may include a light generation layer which emits light, an electron transport layer which transports electrons, a hole transport layer which transports holes, and the like. However, the present disclosure is not limited thereto.

The second electrode ELT2 may be disposed on the light emitting layers EML to cover the light emitting layers EML. The second electrode ELT2 may be disposed on the first light emitting layer EML1 of the first pixel PXL1, the second light emitting layer EML2 of the second pixel PXL2, and the third light emitting layer EML3 of the third pixel PXL3. The second electrode ELT2 may be commonly provided in the first to third pixels PXL1 to PXL3. The second electrode ELT2 may be provided in a plate shape throughout the entire area of the display area DA, but the present disclosure is not limited thereto. Also, the second electrode ELT2 may be a second conductive layer disposed on the pixel circuit layer PCL, but the present disclosure is not limited thereto.

The second electrode ELT2 may be a thin metal layer having a thickness to a degree to which light emitted from each of the first to third light emitting layers EML1 to EML3 can be transmitted therethrough. The second electrode ELT2 may be formed of a metal material to have a relatively thin thickness or be formed of a transparent conductive material. In an example, the second electrode ELT2 may be formed of various transparent conductive materials. For example, the second electrode ELT2 may include at least one of various transparent conductive materials including indium tin oxide (ITO), indium zinc oxide (IZO), indium tin zinc oxide (IZTO), aluminum zinc oxide (AZO), gallium zinc oxide (GZO), zinc tin oxide (ZTO), and gallium tin oxide (GTO). Also, the second electrode ELT2 may be formed substantially transparent or translucent to satisfy a predetermined transmittance. Accordingly, light emitted from each of the first to third light emitting layers EML1 to EML3, which are located on the bottom of the second electrode ELT2, can be emitted upwardly while passing through the second electrode ELT2.

In embodiments, holes injected from the first electrodes ELT1 and electrons injected from the second electrode ELT2 may be transported into the light emitting layers EML in each of the first to third pixels PXL1 to PXL3. Accordingly, excitons may be formed. When the excitons are changed from an excited state to a ground state, light may be generated and emitted in the form of visible rays.

The insulating layer INS may be disposed over the second electrode ELT2. The insulating layer INS may be provided as at least one insulating layer and/or at least one protective layer, covering the first to third light emitting layers EML1 to EML3 and/or the second electrode ELT2.

The insulating layer INS may be provided as a thin film encapsulation layer which seals the light emitting element layer LDL. The thin film encapsulation layer may protect the light emitting element layer LDL from moisture/oxygen, and protect the light emitting element layer LDL from a foreign matter such as dust. For example, the insulating layer INS may be provided in the form of a structure in which at least one inorganic layer and at least one organic layer are alternately stacked.

In some embodiments, the inorganic layer may include at least one of silicon nitride (SiNₓ), silicon oxide (SiOₓ), silicon oxynitride (SiOₓN_{y}), and aluminum oxide (AlₓO_{y}). For example, the organic layer may include at least one of acrylic resin, epoxy resin, phenolic resin, polyamides resin, and polyimides resin. However, embodiments of the inorganic layer and the organic layer are not limited thereto.

The light conversion layer LCPL may be disposed on the insulating layer INS. The light conversion layer LCPL may include banks BNK and light conversion patterns CCP disposed between the banks BNK. Also, the light conversion layer LCPL may include a light scattering pattern LSP including a light scatterer SCT and quantum dot QDs.

The banks BNK may be disposed on the insulating layer INS. The banks BNK may be in contact with the insulating layer INS. The banks BNK may protrude in a thickness direction of the substrate SUB (e.g., the third direction DR3) from the insulating layer INS.

In embodiments, the banks BNK may further include a plurality of refractive layers LY disposed between any one of the banks BNK and the light conversion patterns CCP. The plurality of refractive layers LY will be described in detail later with reference to FIGS. 6 to 12.

Also, the banks BNK may include at least one of an organic material, an inorganic material, and a metal. In an example, the banks BNK may include various inorganic material including silicon nitride (SiNₓ), silicon oxide (SiOₓ), and the like. Alternatively, the banks BNK may include various kinds of organic materials or include a combination of an organic material and an inorganic material. For example, the banks BNK may include niobium oxide (Nb₂O₅), silicon nitride (SiNₓ), tantalum pentoxide (Ta₂O₅), zirconium dioxide (ZrO₂), titanium dioxide (TiO₂), aluminum (Al), titanium (Ti), silver (Ag), and the like. However, the present disclosure is not limited thereto. That is, the material constituting the banks BNK may be variously changed.

In embodiments, the banks BNK may define the first to third emission areas EMA1 to EMA3. The banks BNK may include openings formed therebetween. For example, the openings may be formed by removing the banks BNK. In addition, the light conversion patterns CCP may be disposed in the openings. For example, by using an inkjet printing technique, a first light conversion pattern CCP1 may be supplied and formed in the first emission area EMA1, a second light conversion pattern CCP2 may be supplied and formed in the second emission area EMA2, and the light scattering pattern LSP may be supplied and formed in the third emission area EMA3.

As such, the first and second light conversion patterns CCP1 and CCP2 and the light scattering pattern LSP, which accord with colors, may be disposed in the openings overlapping with the first to third emission areas EMA1 to EMA3, respectively.

The first and second light conversion patterns CCP1 and CCP2 and the light scattering pattern LSP may be disposed on the light emitting element layer LDL. The first and second light conversion patterns CCP1 and CCP2 and the light scattering pattern LSP may be disposed under the color filters CF. That is, the first and second light conversion patterns CCP1 and CCP2 and the light scattering pattern LSP may be disposed between the color filter layer CFL and the light emitting element layer LDL. The first and second light conversion patterns CCP1 and CCP2 and the light scattering pattern LSP may be surrounded by the banks BNK.

The first and second light conversion patterns CCP1 and CCP2 may be configured to change a wavelength of light. The first and second light conversion patterns CCP1 and CCP2 may include quantum dots QD. In an example, the first light conversion pattern CCP1 may include first light conversion particles which convert light of a third color (e.g., blue), which is emitted from a blue light emitting layer, into light of a first color (e.g., red). For example, the first light conversion pattern CCP1 may include a plurality of first quantum dots QD1 dispersed in a matrix material such as base resin. The first quantum dot QD1 may absorb blue light and emit red light by shifting a wavelength of the blue light according to energy transition.

The second light conversion pattern CCP2 may include second light conversion particles which convert light of the third color (e.g., blue), which is emitted from the blue light emitting layer, into light of a second color (e.g., green). For example, the second light conversion pattern CCP2 may include a plurality of second quantum dots QD2 dispersed in a matrix material such as base resin. The second quantum dot QD2 may absorb blue light and emit green light by shifting a wavelength of the blue light according to energy transition.

In an embodiment, light of blue having a relatively short wavelength in a visible light band is incident into the first quantum dot QD1 and the second quantum dot QD2, so that absorption coefficients of the first quantum dot QD1 and the second quantum dot QD2 can be increased. Accordingly, the efficiency of light emitted from the first pixel PXL1 and the second pixel PXL2 can be improved, and excellent color reproduction can be ensured.

The light scattering pattern LSP may be provided to efficiently use light of the third color (or blue) emitted from the blue light emitting layer. For example, the light scattering pattern LSP may include the light scatterer SCT. In an example, the light scatterer SCT of the light scattering pattern LSP may include at least one of silica (SiOₓ) (e.g., silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the present disclosure is not limited thereto.

However, the light scatterer SCT is not disposed only in the third pixel PXL3, and may be selectively included in the first light conversion pattern CCP1 or the second light conversion pattern CCP2. Also, the light scatterer SCT may be omitted such that the light scattering pattern LSP having transparent polymer is provided.

The capping layer CPL may be disposed on the light conversion layer LCPL. The capping layer CPL may cover the banks BNK, and the light conversion patterns CCP and/or the light scattering pattern LSP, disposed between the banks BNK. The capping layer CPL may be disposed throughout the first to third pixels PXL1 to PXL3. The capping layer CPL may prevent the color filter layer CFL and/or light conversion layer LCPL from being damaged or contaminated due to infiltration of an impurity such as moisture or air from the outside. Also, the capping layer CPL may prevent a colorant included in the color filter layer CFL from being diffused into another component.

For example, the capping layer CPL may be an inorganic layer, and include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxynitride (SiOₓN_{y}), and the like.

The color filter layer CFL may be disposed on the capping layer CPL. The color filter layer CFL may include color filters which accord with colors of the first to third pixels PXL1 to PXL3.

For example, the color filter layer CFL may include a first color filter CF1 disposed in the first pixel PXL1 to allow light emitted from the first pixel PXL1 to be selectively transmitted therethrough. The color filter layer CFL may include a second color filter CF2 disposed in the second pixel PXL2 to allow light emitted from the second pixel PXL2 to be selectively transmitted therethrough. Also, the color filter layer CFL may include a third color filter CF3 disposed in the third pixel PXL3 to allow light emitted from the third pixel PXL3 to be selectively transmitted therethrough.

In some embodiments, the first color filter CF1, the second color filter CF2, and the third color filter CF3 may be respectively a red color filter, a green color filter, and a blue color filter, but the present disclosure is not limited thereto. Hereinafter, when an arbitrary color filter among the first color filter CF1, the second color filter CF2, and the third color filter CF3 is designated or when two or more kinds of color filters are inclusively designated, the corresponding color filter or the corresponding color filters are referred to as “a color filter CF” or “color filters CF.”

The first color filter CF1 may be disposed in the first emission area EMA1 of the first pixel PXL1. Also, the first color filter CF1 may include a color filter material which allows light of the first color to be selectively transmitted therethrough. For example, when the first pixel PXL1 is a red pixel, the first color filter CF1 may include a red color filter material.

The second color filter CF2 may be in the second emission area EMA2 of the second pixel PXL2. Also, the second color filter CF2 may include a color filter material which allows light of the second color to be selectively transmitted therethrough. For example, when the second pixel PXL2 is a green pixel, the second color filter CF2 may include a green color filter material.

The third color filter CF3 may be disposed in the third emission area EMA3 of the third pixel PXL3. Also, the third color filter CF3 may include a color filter material which allows light of the third color to be selectively transmitted therethrough. For example, when the third pixel PXL3 is a blue pixel, the third color filter CF3 may include a blue color filter material.

A black matrix BM may be disposed between the color filters CF. The black matrix BM may be disposed in boundary areas of the pixels not to overlap with the emission areas EMA. For example, the black matrix BM may be disposed to overlap the banks BNK.

The black matrix BM may include at least one black matrix material (e.g., at least one light blocking material currently known in the art) among various kinds of black matrix materials and/or a color filter material of a specific color. Also, the black matrix BM may be formed of the same material as the banks BNK, but the present disclosure is not limited thereto. That is, the black matrix BM and the banks BNK may include the same material or different materials.

FIGS. 6 to 13 are enlarged views illustrating portion A shown in FIG. 5 in accordance with various embodiments of the display panel.

Referring to FIG. 6, the banks BNK may include a plurality of refractive layers LY (see FIG. 5) disposed between the bank BNK and the light conversion pattern CCP or the bank BNK and the light scattering pattern LSP.

In some embodiments, a first bank BNK1 may be disposed between the first color conversion pattern CCP1 and the second light conversion pattern CCP2. In addition, a second bank BNK2 may be disposed between the second light conversion pattern CCP2 and the light scattering pattern LSP.

Each of the first and second banks BNK1 and BNK2 may include first and second refractive layers LY1 and LY2 disposed between each of the first and second banks BNK1 and BNK2 and the second light conversion pattern CCP2. Hereinafter, the first bank BNK1 will be described. However, this will be equally applied to the second bank BNK2.

The first and second refractive layers LY1 and LY2 may be provided in a form in which the first and second refractive layers LY1 and LY2 entirely surround the outer circumferential surface of the first bank BNK1. For example, the first bank BNK1 may include a first side surface S1 facing the first light conversion pattern CCP1 and a second side surface S2 opposite to the first side surface S1. Also, the first bank BNK1 may include a top surface TS which connects the first side surface S1 and the second side surface S2 to each other and is opposite to the substrate SUB (see FIG. 5). In addition, the first and second refractive layers LY1 and LY2 may be disposed on each of the first side surface S1, the second side surface S2, and the top surface TS of the first bank BNK1. In particular, the first refractive layer LY1 may be in contact with the first side surface S1, the second side surface S2, and the top surface TS of the first bank BNK1.

The first and second refractive layers LY1 and LY2 may allow light to be output upwardly in the emission area EMA2 (see FIG. 5). For example, first light L1 incident into the first refractive layer LY1 may be reflected to be output upwardly. Second light L2 incident into the second refractive layer LY2 may be reflected to be output upwardly.

The first refractive layer LY1 may be disposed adjacent to the first bank BNK1. In an example, the first refractive layer LY1 may be disposed between the first bank BNK1 and the second light conversion pattern CCP2. The first refractive layer LY1 may directly cover the second side surface S2 of the first bank BNK1 facing the second light conversion pattern CCP2, and be in contact with the first bank BNK1.

The first refractive layer LY1 may have a first refractive index. For example, in a process of forming the first refractive layer LY1, a material having the first refractive index may be entirely applied on the first bank BNK1. The first refractive layer LY1 may be disposed on the first side S1, the second side S2, and the top surface TS of the first bank BNK1.

The second refractive layer LY2 may be disposed adjacent to the first refractive layer LY1. In an example, the second refractive layer LY2 may be disposed between the first refractive layer LY1 and the second light conversion pattern CCP2. The second refractive layer LY2 may directly cover the first refractive layer LY1 facing the second light conversion pattern CCP2, and be in contact with the first refractive layer LY1.

The second refractive layer LY2 may have a second refractive index. For example, in a process of forming the second refractive layer LY2, a material having the second refractive index may be entirely applied on the first refractive layer LY1 covering the first bank BNK1. The second refractive layer LY2 may be disposed to overlap with the first refractive layer LY1 disposed on the first side surface S1, the second side surface S2, and the top surface TS of the first bank BNK1.

In some embodiments, the first refractive index of the first refractive layer LY1 and the second refractive index of the second refractive layer LY2 may be different from each other. In an example, when the first bank BNK1 includes the first and second refractive layers LY1 and LY2, the first refractive layer LY1 may be a low refractive layer, and the second refractive layer LY2 may be a high refractive layer. That is, the first refractive index of the first refractive layer LY1 may be lower than the second refractive index of the second refractive layer LY2. For example, the first refractive index of the first refractive layer LY1 may be 1.2 or more and less than 2.0. In addition, the second refractive index of the second refractive layer LY2 may be 1.4 or more and less than 3.6. However, when the first refractive index is relatively lower than the second refractive index, the present disclosure is not limited thereto.

The first and second refractive layers LY1 and LY2 may include at least one of an organic material, an inorganic material, and a reflective metal. For example, the inorganic material may include silicon nitride (SiNₓ), silicon oxide (SiOₓ), silicon oxynitride (SiOₓN_{y}), aluminum oxide (AlₓO_{y}), and the like. The organic material may include acrylic resin, epoxy resin, phenolic resin, polyamides resin, polyimides resin, and the like. In addition, the reflective metal may include aluminum (Al), silver (Ag), gold (Au), copper (Cu), titanium (Ti), molybdenum (Mo), nickel (Ni), alloys thereof, and the like. However, the present disclosure is not limited thereto.

In embodiments, the first and second refractive layers LY1 and LY2 may have different thicknesses. Each of the first and second refractive layers LY1 and LY2 may have a thickness with which at least some of lights L incident from a light emitting element can cause constructive interference. The thickness with which the constructive interference can be caused may be determined through various methods known in the art.

Since each of the first and second refractive layers LY1 and LY2 has a thickness according to the refractive index thereof, constructive interference can be caused, and reflectivity can be increased. In an example, the first refractive layer LY1 may be a low refractive layer, and have a first thickness d1 in the first direction DR1. The second refractive layer LY2 may be a high refractive layer, and have a second thickness d2 in the first direction DR1. In addition, the first and second refractive layers LY1 and LY2 are disposed substantially flat, and therefore, the first and second thicknesses d1 and d2 may be constant. However, a thickness d of the first and second refractive layers LY1 and LY2 may entirely have 1 to 10,000 nm.

For example, the first refractive layer LY1 may be formed of silicon oxide (SiOₓ), and have a refractive index of 1.47. In addition, the second refractive layer LY2 may be formed of niobium oxide (Nb₂O₅), and have a refractive index of 2.45. When the first thickness d1 of the first refractive layer LY1 is 45.9 nm, the second thickness d2 of the second refractive layer LY2 may be 76.4 nm. When the first thickness d1 of the first refractive layer LY1 is 91.8 nm, the second thickness d2 of the second refractive layer LY2 may be 152.8 nm. Alternatively, when the first thickness d1 of the first refractive layer LY1 is 137.8 nm, the second thickness d2 of the second refractive layer LY2 may be 229.1 nm. However, this is merely illustrative. Since each thickness is changed accordingly a wavelength of incident light and a refractive index, the present disclosure is not limited thereto.

That is, the first and second refractive layers LY1 and LY2 amplify incident light through constructive interference, thereby improving light efficiency. As such, the thickness of the first and second refractive layers LY1 and LY2 is formed according to different refractive indexes, so that luminance can be further improved by increasing the reflectivity of incident light.

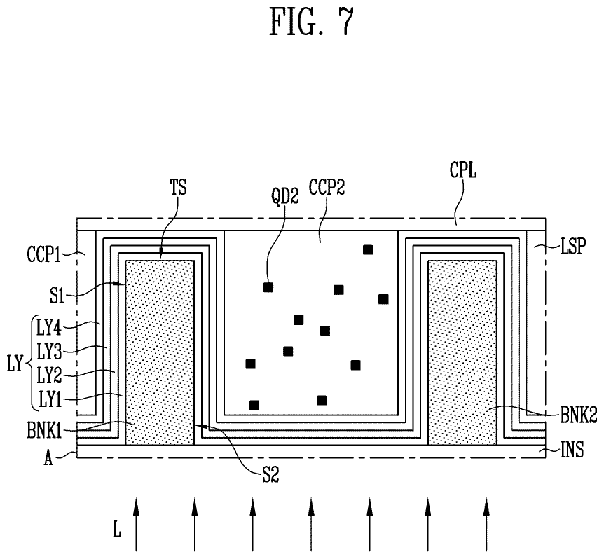

Referring to FIG. 7, each of the first and second banks BNK1 and BNK2 may include first to fourth refractive layers LY1 to LY4 between each of the first and second banks BNK1 and BNK2 and the second light conversion pattern CCP2. Hereinafter, the first bank BNK1 will be described. However, this will be equally applied to the second bank BNK2. In relation to the embodiment shown in FIG. 6, portions different from those of the above-described embodiment will be mainly described to avoid redundancy.

The first to fourth refractive layers LY1 to LY4 may be provided in a form in which the first to fourth refractive layers LY1 to LY4 entirely surround the outer circumferential surface of the first bank BNK1. The first to fourth refractive layers LY1 to LY4 may be disposed on each of the first side surface S1, the second surface S2, and the top surface TS of the first bank BNK1.

The third refractive layer LY3 may be disposed adjacent to the second refractive layer LY2. In an example, the third refractive layer LY3 may be disposed between the second refractive layer LY2 and the second light conversion pattern CCP2. The third refractive layer LY3 may directly cover the second refractive layer LY2 facing the second light conversion pattern CCP2, and be in contact with the second refractive layer LY2.

The third refractive layer LY3 may have a third refractive index. For example, in a process of forming the third refractive layer LY3, a material having the third refractive index may be entirely applied on the second refractive layer LY2. The third refractive layer LY3 may be disposed to overlap with the first and second refractive layers LY1 and LY2 disposed on the first side surface S1, the second side surface S2, and the top surface TS of the first bank BNK1.

The fourth refractive layer LY4 may be disposed adjacent to the third refractive layer LY3. In an example, the fourth refractive layer LY4 may be disposed between the third refractive layer LY3 and the second light conversion pattern CCP2. The fourth refractive layer LY4 may directly cover the third refractive layer LY3 facing the second light conversion pattern CCP2, and be in contact with the third refractive layer LY3.

The fourth refractive layer LY4 may have a fourth refractive index. For example, in a process of forming the fourth refractive layer LY4, a material having the fourth refractive index may be entirely applied on the third refractive layer LY3. The fourth refractive layer LY4 may be disposed to overlap with the first to third refractive layers LY1 to LY3 disposed on the first side surface S1, the second side surface S2, and the top surface TS of the first bank BNK1.

In some embodiments, the first refractive index of the first refractive layer LY1, the second refractive index of the second refractive layer LY2, the third refractive index of the third refractive layer LY3, and the fourth refractive index of the fourth refractive layer LY4 may be different from one another. In an example, when the first bank BNK1 includes the first to fourth refractive layers LY1 to LY4, the first and third refractive layers LY1 and LY3 may be low refractive layers, and the second and fourth refractive layers LY2 and LY4 may be high refractive layers. That is, the third refractive index of the third refractive layer LY3 may be lower than the second refractive index of the second refractive layer LY2. In addition, the third refractive index of the third refractive layer LY3 may be lower than the fourth refractive index of the fourth refractive layer LY4. For example, the first refractive index of the first refractive layer LY1 and the third refractive index of the third refractive layer LY3 may be 1.2 or more and less than 2.0. In addition, the second refractive index of the second refractive layer LY2 and the fourth refractive index of the fourth refractive layer LY4 may be 1.4 or more and less than 3.6. However, when the first and third refractive indexes are relatively lower than the second and fourth refractive indexes, the present disclosure is not limited thereto.

As such, when a plurality of refractive layers LY include even-numbered refractive layers, a low refractive layer and a high refractive layer may be alternatingly and repeatedly disposed on the first bank BNK1.

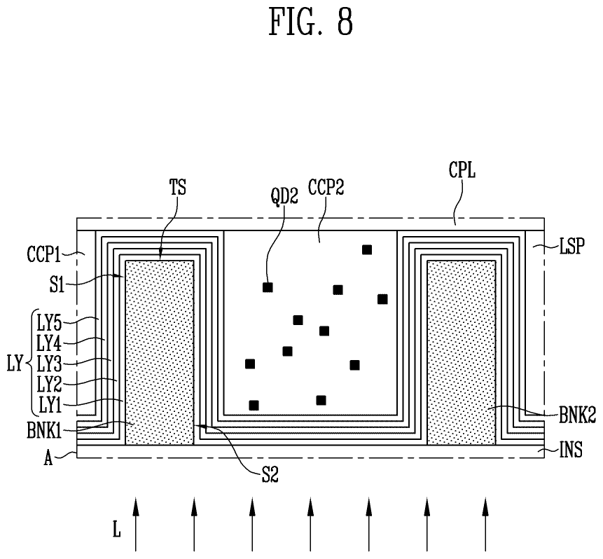

Referring to FIG. 8, each of the first and second banks BNK1 and BNK2 may include first to fifth refractive layers LY1 to LY5 between each of the first and second banks BNK1 and BNK2 and the second light conversion pattern CCP2. Hereinafter, the first bank BNK1 will be described. However, this will be equally applied to the second bank BNK2. In relation to the embodiments shown in FIGS. 6 and 7, portions different from those of the above-described embodiment will be mainly described to avoid redundancy.

The first to fifth refractive layers LY1 to LY5 may be provided in a form in which the first to fifth refractive layers LY1 to LY5 entirely surround the outer circumferential surface of the first bank BNK1. The first to fifth refractive layers LY1 to LY5 may be disposed on each of the first side surface S1, the second surface S2, and the top surface TS of the first bank BNK1.

The fifth refractive layer LY5 may be disposed adjacent to the fourth refractive layer LY4. In an example, the fifth refractive layer LY5 may be disposed between the fourth refractive layer LY4 and the second light conversion pattern CCP2. The fifth refractive layer LY5 may directly cover the fourth refractive layer LY4 facing the second light conversion pattern CCP2, and be in contact with the fourth refractive layer LY4.

The fifth refractive layer LY5 may have a fifth refractive index. For example, in a process of forming the fifth refractive layer LY5, a material having the fifth refractive index may be entirely applied on the fourth refractive layer LY4. The fifth refractive layer LY5 may be disposed to overlap with the first to fourth refractive layers LY1 to LY4 disposed on the first side surface S1, the second side surface S2, and the top surface TS of the first bank BNK1.

In some embodiments, the first refractive index of the first refractive layer LY1, the second refractive index of the second refractive layer LY2, the third refractive index of the third refractive layer LY3, the fourth refractive index of the fourth refractive layer LY4, and the fifth refractive index of the fifth refractive layer LY5 may be different from one another. In an example, when the first bank BNK1 includes the first to fifth refractive layers LY1 to LY5, the first, third, and fifth refractive layers LY1, LY3, and LY5 may be high refractive layers, and the second and fourth refractive layers LY2 and LY4 may be low refractive layers. That is, each of the first and third refractive indexes of the first and third refractive layers LY1 and LY3 may be higher than the second refractive index of the second refractive layer LY2. In addition, the third refractive index of the third refractive layer LY3 may be higher than the fourth refractive index of the fourth refractive layer LY4. The fifth refractive index of the fifth refractive layer LY5 may be higher than the fourth refractive index of the fourth refractive layer LY4. For example, the first refractive index of the first refractive layer LY1, the third refractive index of the third refractive layer LY3, and the fifth refractive index of the fifth refractive layer LY5 may be 1.4 or more and less than 3.6. In addition, the second refractive index of the second refractive layer LY2 and the fourth refractive index of the fourth refractive layer LY4 may be 1.2 or more and less than 2.0. However, when the first, third, and fifth refractive indexes are relatively higher than the second and fourth refractive indexes, the present disclosure is not limited thereto.

As such, when a plurality of refractive layers LY include odd-numbered refractive layers, a high refractive layer and a low refractive layer may be alternatingly and repeatedly disposed from a layer adjacent to the first bank BNK1.

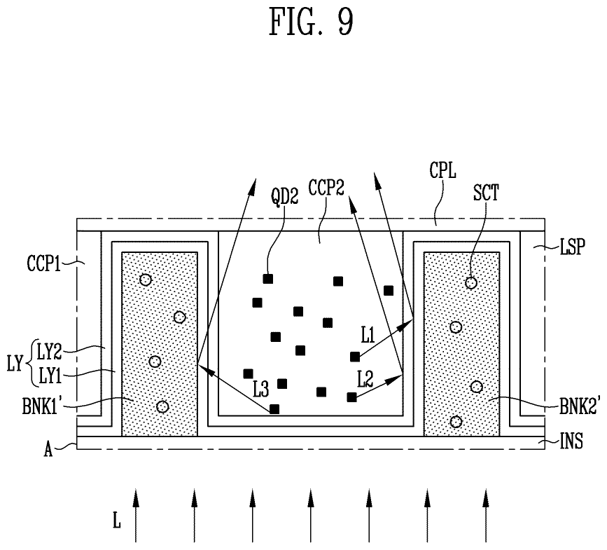

Referring to FIG. 9, each of first and second banks BNK1′ and BNK2′ may further include a light scatterer SCT. In relation to the embodiments shown in FIGS. 6 to 8, portions different from those of the above-described embodiment will be mainly described to avoid redundancy.

In an example, the light scatterer SCT may be included in each of the first and second banks BNK1′ and BNK2′. The light scatterer SCT may include various light scattering particles or light scattering materials. For example, the light scatterer SCT may include at least one of silica (SiOₓ) (e.g., silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the present disclosure is not limited thereto.

Each of the first and second banks BNK1′ and BNK2′ may scatter light incident by the light scatterer SCT in an arbitrary direction regardless of the incident direction. In an example, each of the first and second banks BNK1′ and BNK2′ may allow light to be output upwardly in an emission area. For example, third light L3 incident into the first bank BNK1′ may be reflected to be output upwardly.

As such, the first and second banks BNK1′ and BNK2′ can improve light efficiency through the light scatterer SCT. In an example, the first and second banks BNK1′ and BNK2′ include the light scatterer SCT, so that the plurality of refractive layers LY can be simplified. For example, the first and second banks BNK1′ and BNK2′ may have the same multi-refractive effect as six refractive layers, using only a light scatterer and two refractive layers. In addition, the first and second banks BNK1′ and BNK2′ include the light scatterer SCT, so that white angular dependency (WAD) according to a viewing angle can be improved by varying a reflection direction.

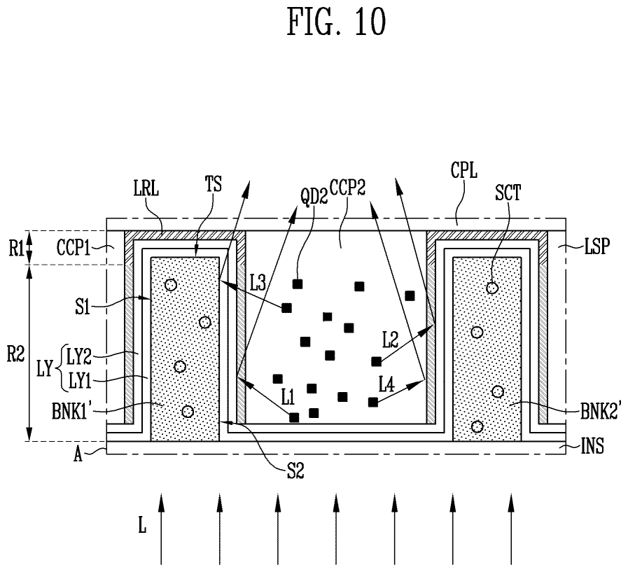

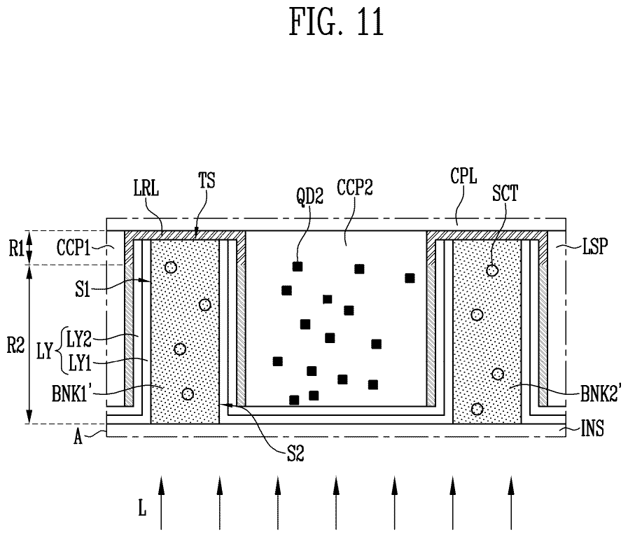

Referring to FIGS. 10 and 11, each of the first and second banks BNK1′ and BNK2′ may include a liquid repellent layer LRL. In relation to the embodiments shown in FIGS. 6 to 9, portions different from those of the above-described embodiment will be mainly described to avoid redundancy.

However, although a case where the first and second banks BNK1′ and BNK2′ include a light scatterer SCT is illustrated in FIG. 10, this may be equally applied to even a case where the first and second banks BNK1′ and BNK2′ do not include the light scatterer SCT.

The first and second banks BNK1′ and BNK2′ may further include the liquid repellent layer LRL by entirely applying a liquid repellent material to the surface of a plurality of refractive layers LY. For example, the liquid repellent layer LRL may be provided in a form in which the liquid repellent layer LRL surrounds the entire outer circumferential surface of a second refractive layer LY2 formed at an outermost portion of the first bank BNK1′. The liquid repellent layer LRL may be disposed to overlap with the first side surface S1, the second side S2, and the top surface TS of each of the first and second banks BNK1′ and BNK2′.

In some embodiments, the liquid repellent layer LRL may be disposed in a form in which the liquid repellent layer LRL is adsorbed on the plurality of refractive layers LY disposed on the first and second banks BNK1′ and BNK2′. The liquid repellent layer LRL may include a first portion R1 which is adjacent to the top surface TS of each of the first and second banks BNK1′ and BNK2′, and has hydrophobicity. Also, the liquid repellent layer LRL may include a second portion R2 which is adjacent to the first side surface S1 and the second side surface S2 of each of the first and second banks BNK1′ and BNK2′, and has hydrophilicity.

The liquid repellent material forming the liquid repellent layer LRL may include an organic polymer material having liquid repellency. For example, the liquid repellent material may include a polymer material in which a fluoro group (F) is mixed with an organic material such as polyimide. In a manufacturing process, after the liquid repellent layer LRL is formed on the outer circumferential surface of the second refractive layer LY2, the fluoro group included in the liquid repellent material of the liquid repellent layer LRL may move in the third direction DR3. Accordingly, the first portion R1 of the liquid repellent layer LRL may have hydrophobicity. The hydrophobicity may mean a property in which the first portion R1 of the liquid repellent layer LRL pushes a discharge liquid in an inkjet printing process since a contact angle with an organic solvent or the like, which is the discharge liquid, is relatively large. On the other hand, the second portion R2 of the liquid repellent layer LRL may have hydrophilicity. The hydrophilicity may mean a property in which the second portion R2 of the liquid repellent layer LRL is soaked in a discharge liquid in an inkjet printing process since a contact angle with an organic solvent or the like, which is the discharge liquid, is relatively small.

In some embodiments, a surface of the second refractive layer LY2, which overlaps with the first portion R1 of the liquid repellent layer LRL in each of the first and second banks BNK1′ and BNK2′, may have hydrophobicity. On the other hand, a surface of the second refractive layer LY2, which overlaps with the second portion R2 of the liquid repellent layer LRL in each of the first and second banks BNK1′ and BNK2′, does not have hydrophobicity but has hydrophilicity.

For example, the first portion R1 of the liquid repellent layer LRL may have hydrophilicity with respect to inks forming the first light conversion pattern CCP1, the second light conversion pattern CCP2, and the light scattering pattern LSP. Accordingly, each of the first and second banks BNK1′ and BNK2′ has hydrophilicity given by the first portion R1 of the liquid repellent layer LRL, so that the first light conversion pattern CCP1, the second light conversion pattern CCP2, and the light scattering pattern LSP can be accurately disposed between the first and second banks BNK1′ and BNK2′.

In addition, the liquid repellent material forming the liquid repellent layer LRL may further include a light scatterer or be a transparent material. The liquid repellent layer LRL may scatter incident light in an arbitrary direction regardless of the incident direction. Accordingly, the reflectivity can be additionally improved through the light repellent layer LRL, and the WAD according to the viewing angle can be improved.

Referring to FIG. 11, the top surface TS of each of the first and second banks BNK1′ and BNK2′ and the liquid repellent layer LRL may be in direct contact with each other without having the plurality of refractive layers LY interposed therebetween. In relation to the embodiment shown in FIG. 10, portions different from those of the above-described embodiment will be mainly described to avoid redundancy.

Each of the first and second banks BNK1′ and BNK2′ may include first and second refractive layers LY1 and LY2 between each of the first and second banks BNK1′ and BNK2′ and the second light conversion pattern CCP.

The first and second refractive layers LY1 and LY2 may be provided in a form in which the first and second refractive layers LY1 and LY2 surround a side surface of the outer circumferential surface of each of the first and second banks BNK1′ and BNK2′. For example, in the first bank BNK1′, the first and second refractive layers LY1 and LY2 may be disposed on the first side S1 facing the first light conversion pattern CCP1 and the second side S2 opposite to the first side surface S1. On the other hand, the first and second refractive layers LY1 and LY2 may not be disposed on the top surface TS which connects the first side surface S1 and the second side surface S2 to each other and is opposite to the substrate SUB (see FIG. 5). As such, the plurality of refractive layers LY disposed on the top surface TS of each of the first and second banks BNK1′ and BNK2′ may be removed.

In some embodiments, a liquid repellent material may be entirely applied on the top surface TS of each of the first and second banks BNK1′ and BNK2′ and the surface of the second refractive layer LY2, to form a liquid repellent layer LRL. Accordingly, the liquid repellent layer LRL may be disposed to be in direct contact with the top surface TS of each of the first and second banks BNK1′ and BNK2′. Also, the liquid repellent layer LRL may be disposed to be in direct contact with the second refractive layer LY2 overlapping with the first and second side surfaces S1 and S2 of each of the first and second banks BNK1′ and BNK2′.

The liquid repellent layer LRL may include a first portion R1 which is adjacent to the top surface TS of each of the first and second banks BNK1′ and BNK2′, and has hydrophobicity. Also, the liquid repellent layer LRL may include a second portion R2 which is adjacent to the first side surface S1 and the second side surface S2 of each of the first and second banks BNK1′ and BNK2′, and has hydrophilicity.

In the first and second banks BNK1′ and BNK2′, the top surface TS of each of the first and second banks BNK1′ and BNK2′, which overlaps with the first portion R1 of the liquid repellent layer LRL, may have hydrophobicity. On the other hand, in the first and second banks BNK1′ and BNK2′, the surface of the second refractive layer LY2, which overlaps with the second portion R2 of the liquid repellent layer LRL, may have hydrophilicity instead of the hydrophobicity.

Referring back to FIG. 11, a capping layer CPL may be disposed on the top surface TS of each of the first and second banks BNK1′ and BNK2′ without having the plurality of refractive layers LY interposed therebetween. The capping layer CPL may be in contact with the first portion R1 of the liquid repellent layer LRL.

As such, the first portion R1 of the liquid repellent layer LRL having hydrophobicity is disposed between the first and second banks BNK1′ and BNK2′ and the capping layer CPL, so that the same effect as shown in FIG. 10 can be provided even when the plurality of refractive layers LY are removed from the top surface TS of each of the first and second banks BNK1′ and BNK2′.

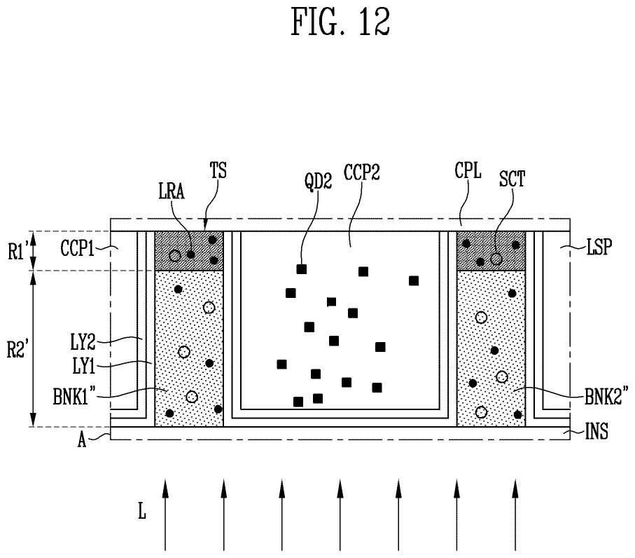

Referring to FIG. 12, each of first and second banks BNK1″ and BNK2″ may further include a liquid repellent additive LRA. In relation to the embodiment shown in FIG. 9, portions different from those of the above-described embodiment will be mainly described to avoid redundancy.

In some embodiments, the first and second banks BNK1″ and BNK2″ may have hydrophobicity given by the liquid repellent additive LRA. For example, the liquid repellent additive LRA is a surface modifying agent, and may be vinyl-based polymer having a perfluoroalkyl group (Rf group) in a side chain, silicon containing a perfluoroalkyl group, or the like. However, the present disclosure is not limited thereto.

The first and second banks BNK1″ and BNK2″ may include a first portion R1 adjacent to a top surface TS of each of the first and second banks BNK1″ and BNK2″ and a second portion R2 located between the first portion R1 and the substrate SUB (see FIG. 5).

The first portion R1 of each of the first and second banks BNK1″ and BNK2″ may have hydrophobicity. The second portion R2 of each of the first and second banks BNK1″ and BNK2″ may have hydrophilicity. For example, in a manufacturing process, when the first and second banks BNK1″ and BNK2″ are formed on the insulating layer INS, the first portion R1 may include a fluoro group (F) while the fluoro group in the first and second banks BNK1″ and BNK2″ moves in the third direction DR3 to the surface of the first and second banks BNK1″ and BNK2″. Therefore, the first portion R1 may have hydrophobicity. On the other hand, the second portion R2 may have hydrophilicity.

Since the first portion R1 of each of the first and second banks BNK1″ and BNK2″ has hydrophobicity, the top surface TS of each of the first and second banks BNK1″ and BNK2″, which is exposed to the outside, may also have hydrophobicity. On the other hand, the second portion R2 of each of the first and second banks BNK1″ and BNK2″ having hydrophilicity may not be exposed to the outside because the second portion R2 is surrounded by the first and second refractive layers LY1 and LY2.

For example, the top surface TS of each of the first and second banks BNK1″ and BNK2″ may have liquid repellency with respect to inks forming the first light conversion pattern CCP1, the second light conversion pattern CCP2, and the light scattering pattern LSP. Accordingly, the first light conversion pattern CCP1, the second light conversion pattern CCP2, and the light scattering pattern LSP can be prevented from being applied on the top surface TS of each of the first and second banks BNK1″ and BNK2″ in an inkjet process. Thus, each of the first light conversion pattern CCP1, the second light conversion pattern CCP2, and the light scattering pattern LSP can be readily formed in the emission area EMA (see FIG. 5). In addition, mixture between the first light conversion pattern CCP1, the second light conversion pattern CCP2, and the light scattering pattern LSP is prevented, so that the quality of the display device can be improved.

Referring back to FIG. 12, a capping layer CPL may be disposed on the top surface TS of each of the first and second banks BNK1″ and BNK2″. The capping layer CPL may be formed directly on the top surface TS of each of the first and second banks BNK1″ and BNK2″, to be in contact with the first portion R1. The capping layer CPL may be in direct contact with the first portion R1 without having any refractive layers interposed therebetween. Therefore, the capping layer CPL may directly cover the first and second banks BNK1″ and BNK2″, the first light conversion pattern CCP1, the second light conversion pattern CCP2, and the light scattering pattern LSP.

As such, the first portion R1 of each of the first and second banks BNK1″ and BNK2″ has hydrophobicity, so that the first light conversion pattern CCP1, the second light conversion pattern CCP2, and the light scattering pattern LSP (see FIG. 11) can be removed between the first and second banks BNK1″ and BNK2″ and the capping layer CPL.

As such, the first and second refractive layers LY1 and LY2 are disposed on the first and second banks BNK1″ and BNK2″, so that the reflectivity of incident light can be increased, thereby further improving the luminance. At the same time, the first and second banks BNK1″ and BNK2″ include the light scatterer SCT and the liquid repellent additive LRA, so that the plurality of refractive layers LY can be simplified and the reflection direction can be varied.

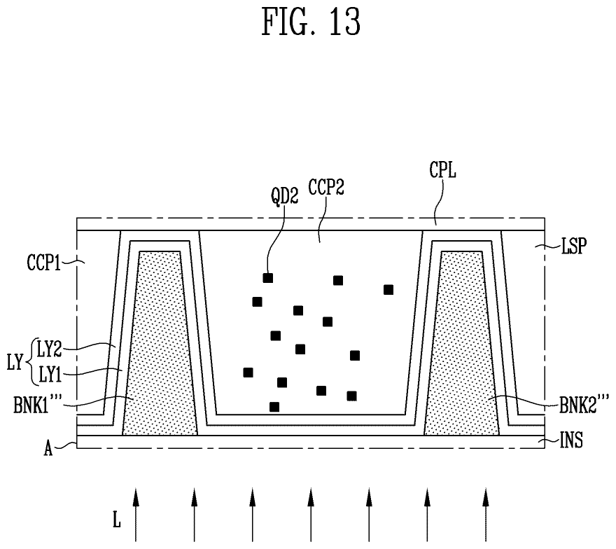

Referring to FIG. 13, each of first and second banks BNK1′″ and BNK2′″ may include first and second refractive layers LY1 and LY2 between each of first and second banks BNK1′″ and BNK2′″ and the second light conversion pattern CCP. The first and second banks BNK1′″ and BNK2′″ may have various shapes.

In some embodiments, the first and second banks BNK1′″ and BNK2′″ may be formed to have an inclined surface inclined at an angle in a predetermined range with respect to the substrate SUB (see FIG. 5). As shown in FIG. 13, the first and second banks BNK1′″ and BNK2′″ may have a trapezoidal cross section. However, this is merely illustrative, and the present disclosure is not limited thereto. For example, the first and second banks BNK1′″ and BNK2′″ may have a cross section such as a rectangle, a square, a reversed trapezoid, or a semi-ellipse.

In some embodiments, a plurality of refractive layers LY may be formed to have flat surfaces on a top surface TS of each of the first and second banks BNK1′″ and BNK2′″. For example, each of the plurality of refractive layers LY may be formed to have a concave surface, a convex surface, an elliptical surface, an angular surface, or the like. However, this is merely illustrative, and the present disclosure is not limited thereto.

In accordance with the present disclosure, there can be provided a display device having improved display quality.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a substrate;
a light emitting element disposed in an emission area on the substrate; and
a light conversion layer disposed on the light emitting element to overlap the light emitting element, the light conversion layer including banks, a light conversion pattern disposed between adjacent banks, and a plurality of refractive layer disposed on the banks,
wherein the plurality of refractive layers include a first refractive layer disposed on the banks and having a first refractive index and a second refractive layer disposed on the banks on the first refractive layer and having a second refractive index different from the first refractive index.

2. The display device of claim 1, wherein the first refractive index is lower than the second refractive index.

3. The display device of claim 2, wherein the first refractive layer and the second refractive layer are alternatingly and repeatedly disposed on the banks.

4. The display device of claim 2, wherein the plurality of refractive layers further include:
a third refractive layer disposed on the second refractive layer, the third refractive layer having a refractive index lower than the second refractive index; and
a fourth refractive layer disposed on the third refractive layer, the fourth refractive layer having a refractive index higher than the third refractive index.

5. The display device of claim 1, wherein the plurality of refractive layers further include a third refractive layer disposed on the second refractive layer, the third refractive layer having a refractive index different from the second refractive index, and
wherein each of the first refractive index and the third refractive index is higher than the second refractive index.

6. The display device of claim 5, wherein the plurality of refractive layers further include:
a fourth refractive layer disposed on the third refractive layer, the fourth refractive layer having a refractive index lower than the third refractive index; and
a fifth refractive layer disposed on the fourth refractive layer, the fifth refractive layer having a refractive index higher than the fourth refractive index.

7. The display device of claim 1, wherein each of the plurality of refractive layers includes at least one of an organic material, an inorganic material, and a reflective metal.

8. The display device of claim 1, wherein each of the plurality of refractive layers has a predetermined thickness such that at least some of lights incident from the light emitting element form constructive interference.

9. The display device of claim 1, wherein the plurality of refractive layers have a thickness of 1 nm or more and 10000 nm or less.

10. The display device of claim 1, wherein the banks include at least one of an organic material, an inorganic material, and a metal, and
wherein the banks further include a light scatterer.

11. The display device of claim 1, wherein one of the banks includes a first side surface facing the light conversion pattern, a second side surface opposite to the first side surface, and a top surface which connects the first side surface and the second side surface to each other and is opposite to the substrate, and
wherein the first refractive layer is in contact with the first side surface and the second side surface.

12. The display device of claim 11, wherein the first refractive layer is in contact with the top surface.

13. The display device of claim 11, wherein the banks further include a liquid repellent additive.

14. The display device of claim 13, wherein the one of the banks includes a first portion disposed adjacent to the top surface and a second portion disposed between the first portion and the substrate, and
wherein the first portion has hydrophobicity and the second portion has hydrophilicity.

15. The display device of claim 14, further comprising a capping layer covering the light conversion layer,
wherein the capping layer and the first portion are in direct contact with each other.

16. The display device of claim 11, wherein the light conversion layer further includes a liquid repellent layer.

17. The display device of claim 16, wherein the liquid repellent layer includes a first portion disposed adjacent to the top surface and a second portion disposed between the first portion and the substrate, and
wherein the first portion has hydrophobicity and the second portion has hydrophilicity.

18. The display device of claim 17, further comprising a capping layer covering the light conversion layer,
wherein the first portion is disposed between the banks and the capping layer, and
wherein the banks and the first portion are in direct contact with each other.

19. The display device of claim 1, wherein the one of the banks has a square shape, a rectangular shape, or a trapezoidal shape in a cross-sectional view.
